(19) United States
(12) Patent Application Publication
(10) Pub. No.: US 2025/0006477 A1
(43) Pub. Date: Jan. 2, 2025

(54) PLASMA DIAGNOSTIC APPARATUS, AND APPARATUS FOR FABRICATING SEMICONDUCTOR DEVICES USING THE SAME

(71) Applicant: Samsung Electronics Co., Ltd., Suwon-si (KR)

(72) Inventors: Haewook PARK, Suwon-si (KR); Juhyun KIM, Suwon-si (KR); Younsok CHOI, Suwon-si (KR)

(73) Assignee: Samsung Electronics Co., Ltd., Suwon-si (KR)

(21) Appl. No.: 18/605,110

(22) Filed: Mar. 14, 2024

(30) Foreign Application Priority Data
Jun. 27, 2023 (KR) 10-2023-0082813

(51) Int. Cl. H01J 37/32; G01R 19/25; H01L 21/683

(52) U.S. Cl. CPC H01J 37/3299; G01R 19/25; H01J 37/32715; H01L 21/6833; H01J 2237/2007; H01J 2237/24564; H01J 2237/2485

(57) ABSTRACT

A plasma diagnosis apparatus comprising; an upper substrate, a lower substrate stacked with the upper substrate, at least one probe on the upper substrate, a plasma diagnosis circuit mounted in the lower substrate and configured to diagnose plasma in a chamber through the probe, a wireless communication circuit mounted in the lower substrate and configured to wirelessly transmit a result of the plasma diagnosis circuit to an external device, a battery mounted in the lower substrate and configured to supply power to the plasma diagnosis circuit and the wireless communication circuit, and a wireless charging circuit mounted in the lower substrate and configured to wirelessly charge the battery. The plasma diagnosis circuit includes a transformer, a first circuit connected to a primary wound line of the transformer, a second circuit connected between a secondary wound line of the transformer and the probe, a current detection circuit connected to the primary wound line of the transformer, and a signal processing circuit configured to generate data with diagnostic characteristics of the plasma based on an output of the current detection circuit.

### CROSS-REFERENCE TO RELATED APPLICATION(S)

This application claims benefit of priority to Korean Patent Application No. 10-2023-0082813 filed on Jun. 27, 2023 in the Korean Intellectual Property Office, the disclosure of which is incorporated herein by reference in its entirety.

### BACKGROUND

Various example embodiments relate to a plasma diagnosis apparatus and an apparatus for fabricating semiconductor devices using the same.

In an apparatus for fabricating a semiconductor device using plasma to perform a semiconductor process such as deposition, etching, or the like, various methods for measuring characteristics of the plasma have been proposed. An optical method of determining characteristics of plasma by measuring light emitted from or absorbed by the plasma, an electrical method of determining characteristics of plasma in an electrical manner using a probe, and the like, have been proposed.

### SUMMARY

Various example embodiments provide a plasma diagnosis apparatus and an apparatus for fabricating a semiconductor device using the same. The plasma diagnosis apparatus may be employed to verify the reliability of a plasma generated by the apparatus for fabricating a semiconductor device to improve yield of the semiconductor device. By putting the plasma diagnosis apparatus into the apparatus for fabricating a semiconductor device before the start and/or after the end of the semiconductor process using a plasma. The plasma diagnosis apparatus may collect data necessary diagnosing the generation of the plasma inside the apparatus for fabricating a semiconductor device.

According to various example embodiments, a plasma diagnosis apparatus comprising; an upper substrate, a lower substrate stacked with the upper substrate, at least one probe on the upper substrate, a plasma diagnosis circuit mounted in the lower substrate and configured to diagnose plasma in a chamber through the probe, a wireless communication circuit mounted in the lower substrate and configured to wirelessly transmit a result of the plasma diagnosis circuit to an external device, a battery mounted in the lower substrate and configured to supply power to the plasma diagnosis circuit and the wireless communication circuit, and a wireless charging circuit mounted in the lower substrate and configured to wirelessly charge the battery. The plasma diagnosis circuit includes a transformer, a first circuit connected to a primary wound line of the transformer, a second circuit connected between a secondary wound line of the transformer and the probe, a current detection circuit connected to the primary wound line of the transformer, and a signal processing circuit configured to generate data with diagnostic characteristics of the plasma based on an output of the current detection circuit.

According to various example embodiments, a plasma diagnosis apparatus comprising; at least one probe, a transformer connected to the probe, a current sensing resistor connected to a primary wound line of the transformer, an operational amplifier connected to the current sensing resistor, a pre-amplifier connected to an output terminal of the operational amplifier, and a signal processing circuit connected to the operational amplifier. A current signal from plasma introduced through the probe is input to the operational amplifier through the transformer and the current sensing resistor, the operational amplifier and the pre-amplifier are configured to convert the current signal into an output voltage signal, and the signal processing circuit is configured to convert the output voltage signal into frequency domain data.

According to various example embodiments, an apparatus for fabricating a semiconductor device, comprising; a chamber, an electrostatic chuck in a space inside the chamber, a gas supplier configured to supply at least one of a source gas or a reaction gas, a power supplier configured to supply bias power to an electrode in the space inside the chamber, and a controller configured to control the power supplier, the gas supplier, and the electrostatic chuck. A plasma diagnosis apparatus is on the electrostatic chuck, the controller is configured to control the power supplier to supply the bias power to the electrode such that plasma is generated in the space inside the chamber, and the controller is configured to control the gas supplier to supply at least one of the source gas or the reaction gas, the controller is configured to control the gas supplier, the power supplier, and the electrostatic chuck using data acquired from the plasma by the plasma diagnosis apparatus, and the plasma diagnosis apparatus includes a probe, a current detection circuit detecting a current signal introduced through the probe, and a transformer having a primary wound line connected to the current detection circuit and a secondary wound line connected to the probe.

### BRIEF DESCRIPTION OF DRAWINGS

The above and other aspects, features, and advantages of various example embodiments may be more clearly understood from the following detailed description, taken in conjunction with the accompanying drawings, in which:

FIG. 1 is a view illustrating a system according to some example embodiments.

FIG. 2 is a schematic view of a system for fabricating a semiconductor device according to some example embodiments.

FIG. 3 is a schematic view of an apparatus for fabricating a semiconductor device according to some example embodiments.

FIG. 4 is a view illustrating a plasma diagnosis apparatus according to some example embodiments.

FIG. 5 is a view illustrating a cross-section of the plasma diagnosis apparatus illustrated in FIG. 4, taken along direction I-I′, according to some example embodiments.

FIGS. 6 to 9 are circuit diagrams illustrating a plasma diagnosis circuit according to some example embodiments.

FIGS. 10A to 10C illustrate outputs of a current detection circuit according to some example embodiments.

FIGS. 11A to 11C illustrate results of converting the output of the current detection circuit of FIGS. 10A to 10C into frequency domains.

FIG. 12 illustrates plasma density diagnosis results according to some example embodiments.

FIG. 13 is a flowchart illustrating a plasma diagnosis process according to some example embodiments.

### DETAILED DESCRIPTION

Hereinafter, various example embodiments of the present inventive concept may be described with reference to the accompanying drawings.

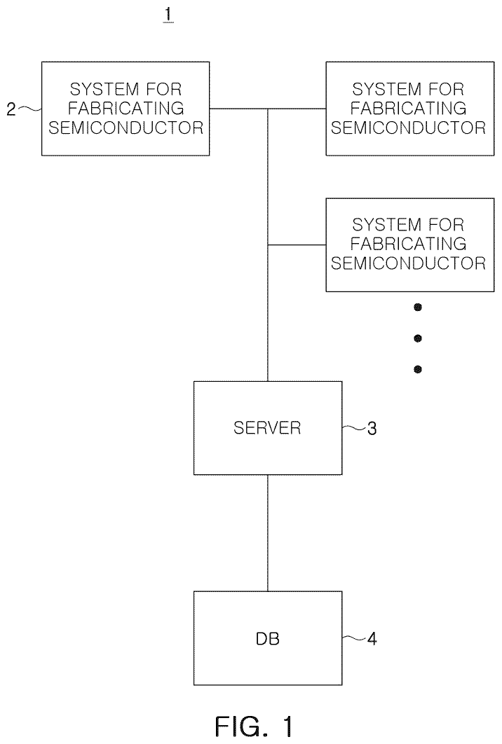

FIG. 1 is a view illustrating a system according to some example embodiments.

Referring to FIG. 1, system 1 may perform various diagnosis and monitoring of plasma that directly affects semiconductor process results. In particular, the system 1 of the present inventive concept may diagnose a state of the plasma in-situ by inserting a plasma diagnosis apparatus implemented in a wafer form.

The present inventive concept discloses a plasma diagnosis apparatus that may be transported and auto loaded by a front opening unified pod (FOUP), and the plasma diagnosis apparatus may be a wireless device that operates using a battery as a power source. In various example embodiments, the plasma diagnosis apparatus may be introduced into a chamber of a system 2 for fabricating a semiconductor device that performs a semiconductor process.

For example, the plasma diagnosis apparatus may be manufactured using a silicon material. In various example embodiments, the plasma diagnosis apparatus may have a thickness of 1.4 mm or less and a weight of 210 g or less. In addition, as an example, a low-capacity battery of about 20 mAh and a low-power integrated circuit (IC) may be applied to the plasma diagnosis apparatus. However, example embodiments are not limited thereto. For example, the plasma diagnosis apparatus may satisfy conditions for being transportable by the FOUP and may be actually introduced into the chamber of the system 2.

A plasma diagnosis apparatus according to various example embodiments may be implemented in a wafer form and may be fixed on an electrostatic chuck of the system 2. In some example embodiments, instead of an electrostatic chuck there may be a vacuum chuck, a non-chucking substrate support unit, or the like. However, example embodiments are not limited thereto. Data for diagnosing characteristics of the plasma may be collected in a state in which the plasma is generated according to conditions for performing a semiconductor process inside the chamber of the system 2. In addition, since the plasma diagnosis apparatus may be formed of a silicon material such as a wafer, it is possible to minimize problems of chamber contamination or arcing before and after insertion of the plasma diagnosis apparatus.

According to various example embodiments, data collected by the plasma diagnosis apparatus may be transmitted to a server 3, and the server 3 may diagnose characteristics of plasma generated inside the chamber based on the data received from the plasma diagnosis apparatus. In this case, a density, an electron temperature, an ion density, an ion flux, or the like of the plasma may be diagnosed. The server 3 may transmit at least one of data received from the plasma diagnosis apparatus or plasma diagnosis results to a database (DB) 4. The DB 4 may store information received from the server 3, and may transmit information requested by the server 3 to the server 3.

According to various example embodiments, the system 2 may include an apparatus for fabricating a semiconductor device. The apparatus for fabricating a semiconductor device may include a chamber, an electrostatic chuck installed in a space inside the chamber, a gas supplier supplying at least one of a source gas or a reaction gas, a power supplier supplying bias power to an electrode installed in the space inside the chamber, and a controller controlling the power supplier, the gas supplier, and the electrostatic chuck.

In various example embodiments, when a plasma diagnosis apparatus is disposed on the electrostatic chuck, the controller may control the power supplier to supply the bias power to the electrode such that plasma is generated in the space inside the chamber and may control the gas supplier to supply at least one of the source gas or the reaction gas. Also, the controller may control the gas supplier, the power supplier, and the electrostatic chuck using data acquired from the plasma by the plasma diagnosis apparatus.

The plasma diagnosis apparatus may include a probe, a current detection circuit detecting a current signal introduced through the probe, and a transformer having a primary wound line connected to the current detection circuit and a secondary wound line connected to the probe.

While the gas supplier supplies at least one of the source gas or the reaction gas to the space inside the chamber, the power supplier may supply the bias power to the electrode installed in the space inside the chamber, and in this case, the plasma may be generated. For example, the plasma may be formed in a space above the electrostatic chuck installed in the space inside the chamber and in which a wafer or the like is seated. In an embodiment, the plasma may be formed in the space inside the chamber in a state in which a plasma diagnosis apparatus implemented in a wafer form is seated on the electrostatic chuck, and the plasma diagnosis apparatus may acquire data necessary for diagnosing the plasma. For example, the plasma diagnosis apparatus may include the probe, and may acquire data necessary for plasma diagnosis by detecting a current signal introduced through the probe while a predetermined (or, alternatively a desired) voltage signal is applied to the probe.

In various example embodiments, a ground of the current detection circuit for detecting the current signal introduced through the probe and a ground of the probe may be separated from each other by the transformer. For example, a primary side to which the signal detection circuit is connected and a secondary side to which the probe is connected may be insulated from each other by the transformer. Therefore, noise included in the current signal introduced through the probe may be attenuated due to insulation characteristics of the transformer, and performance of the plasma diagnosis apparatus may be improved.

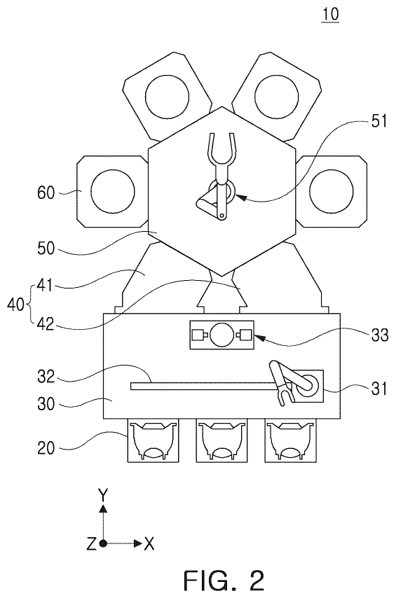

FIG. 2 is a schematic view of a system for fabricating a semiconductor device according to an embodiment.

Referring to FIG. 2, a system 10 for fabricating a semiconductor device according to an embodiment may include a wafer transfer device 30, a load lock chamber 40, a transfer chamber 50, a plurality of apparatuses 60 for fabricating the semiconductor, and the like. For example, the wafer transfer device 30 may receive a wafer through a container such as a FOUP 20 inside a line on which the system 10 is disposed. The wafer transfer device 30 may transfer the wafer received through the FOUP 20 to the load lock chamber 40 or may receive the wafer on which a semiconductor process is completed in an apparatus 60 for fabricating the semiconductor from the load lock chamber 40 and may be accommodated in the FOUP 20.

The wafer transfer device 30 may include a wafer transfer robot 31 having an arm capable of holding a wafer, a rail unit 32 moving the wafer transfer robot 31, and an aligner 33 aligning wafers, and the like. Assuming an operation of transferring the wafer from the FOUP 20 to the load lock chamber 40, the wafer transfer robot 31 may take out the wafer stored in the FOUP 20 and place the same on the aligner 33. The aligner 33 may rotate the wafer to align the wafer in a predetermined (or, alternatively a desired) direction. When wafer alignment is completed in the aligner 33, the wafer transfer robot 31 may take the wafer out of the aligner 33 and transfer the same to the load lock chamber 40.

The load lock chamber 40 may be connected to the wafer transfer device 30 and may include a loading chamber 41 in which wafers carried into the apparatus 60 temporarily stay for semiconductor processing, and an unloading chamber 42 in which wafers unloaded from the apparatus 60 temporarily stay after the process is completed. When the wafers aligned in the aligner 33 are loaded into the loading chamber 41, a space inside the loading chamber 41 may be depressurized to prevent an external contaminant from entering.

The load lock chamber 40 may be connected to the transfer chamber 50, and the plurality of apparatuses 60 may be connected around the transfer chamber 50. A wafer transfer robot 51 for transferring the wafer between the load lock chamber 40 and the plurality of apparatuses 60 may be disposed inside the transfer chamber 50. The wafer transfer robot 31 of the wafer transfer device 30 may be referred to as a first wafer transfer robot, and the wafer transfer robot 51 of the transfer chamber 50 may be referred to as a second wafer transfer robot.

Each of the plurality of apparatuses 60 may perform a semiconductor process on the wafer. For example, the semiconductor process performed by the plurality of apparatuses 60 may include a deposition process, an etching process, an ashing process, an exposure process, an annealing process, a polishing process, an ion implantation process, or the like.

The plasma may be formed inside at least one of the plurality of apparatuses 60 to perform at least some of the above-mentioned semiconductor processes. The plasma may be formed on a wafer, a mask, a mother substrate for a display, or the like, which may be subject to semiconductor processing, and distribution or yield of the semiconductor process may vary depending on how the plasma is formed. Therefore, prior to actually performing the semiconductor process in the apparatuses 60, an operation of forming the plasma and diagnosing and analyzing characteristics thereof may be conducted.

In various example embodiments, characteristics of plasma formed in an apparatus 60 for fabricating a semiconductor device may be diagnosed using a plasma diagnosis apparatus implemented in a wafer form. For example, the plasma diagnosis apparatus may perform auto-loading through a FOUP 20 and may be put into a chamber to in-situ diagnose the plasma formed inside the chamber.

A plasma diagnosis apparatus according to various example embodiments may include a plasma diagnosis circuit including a transformer. A primary wound line of the transformer may be connected to a current detection circuit, and a secondary wound line of the transformer may be connected to a probe. For example, a ground of the current detection circuit connected to the primary wound line by the transformer and a ground of the probe connected to the secondary wound line may be separated from each other. Therefore, it is possible to attenuate unnecessary noise introduced through the probe into the current detection circuit, and thus, the plasma may be accurately diagnosed.

By diagnosing characteristics of the plasma in advance using the plasma diagnosis apparatus and controlling the apparatus 60 using diagnosis results, it is possible to improve the uniformity, density, distribution, and other characteristics of the plasma which can result in an improved semiconductor process and/or improve the yields of the semiconductor devices fabricated via said semiconductor process.

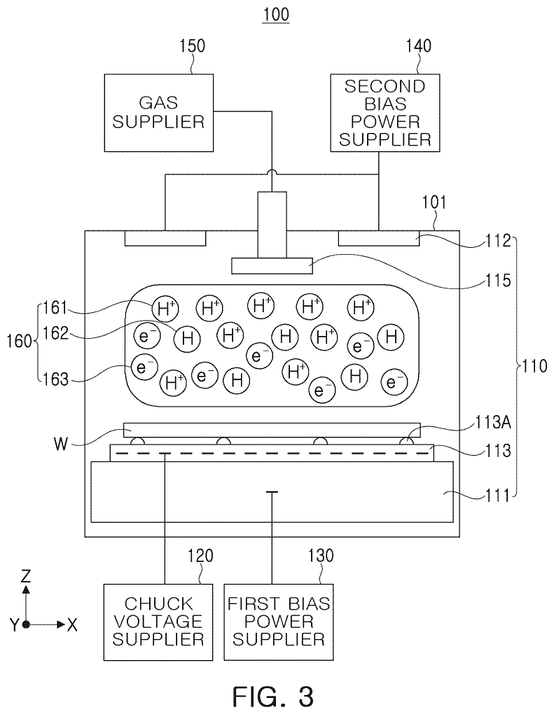

FIG. 3 is a schematic view of an apparatus for fabricating a semiconductor device according to various example embodiments.

An apparatus 100 for fabricating a semiconductor device according to an embodiment may be an apparatus for performing a semiconductor process using plasma. The apparatus 100 may include a chamber 110, a chuck voltage supplier 120, a first bias power supplier 130, a second bias power supplier 140, a gas supplier 150, and the like. However, example embodiments are not limited thereto.

The chamber 110 may include a housing 101, a first bias electrode 111, a second bias electrode 112, an electrostatic chuck 113, a gas flow path 115, and the like. A process target to perform the semiconductor process may be seated on the electrostatic chuck 113. In an embodiment illustrated in FIG. 3, the process target is illustrated as a wafer W, but the process target may be changed as a mother substrate for a display, a mask, and the like. However, example embodiments are not limited thereto.

As illustrated in FIG. 3, a protrusion 113A having a protruding shape may be formed in plural on an upper surface of the electrostatic chuck 113. A wafer W may be seated on the protrusion 113A, and thus a space may be formed between the upper surface of the electrostatic chuck 113 and the wafer W. For example, the space between the upper surface of the electrostatic chuck 113 and the wafer W may be filled with helium gas or the like for the purpose of cooling the wafer W. However, example embodiments are not limited thereto.

In various example embodiments, the wafer W may be fixed on the electrostatic chuck 113 by a Coulomb force generated from a chuck voltage supplied to the electrostatic chuck 113 by the chuck voltage supplier 120. For example, the chuck voltage supplier 120 may supply the chuck voltage to the electrostatic chuck 113 in the form of a constant voltage, and the chuck voltage may have a magnitude of hundreds to thousands of voltages. However, example embodiments are not limited thereto.

Plasma gas may be introduced through the gas flow path 115 to perform a semiconductor process. The first bias power supply 130 may supply first bias power to the first bias electrode 111 located below the electrostatic chuck 113, and the second bias power supply 140 may supply second bias power to the second bias electrode 112 located on the upper part of the electrostatic chuck 113. The first bias power supplier 130 and the second bias power supplier 140 may include a radio frequency (RF) power source for supplying bias power, respectively.

Plasma 160 including an ion 161, a radical 162, and an electron 163 of the plasma gas may be generated in the space above the wafer W by the first bias power and the second bias power, and reactive gas may be activated by the plasma 160 to increase reactivity. For example, when the apparatus 100 is an etching device, the first bias power supplied from the first bias power supplier 130 to the first bias electrode 111 may accelerate the ion 161, the radical 162, the electron 163, or the like of the reaction gas into the wafer W. At least some of the semiconductor substrate or layers included in the wafer W may be dry etched by the ion 161, the radical 162, the electron 163, or the like of the reaction gas. However, example embodiments are not limited thereto.

In various example embodiments, prior to performing an etching process, a deposition process, or the like using the plasma 160, a plasma diagnosis apparatus, separately manufactured instead of the wafer W, may be disposed on the electrostatic chuck 113 to generate the plasma 160. The plasma diagnosis apparatus may acquire data necessary for analyzing characteristics of the plasma 160, and, for example, the plasma diagnosis apparatus may detect a current signal introduced from the plasma 160 through a probe or a plurality of probes.

The data acquired by the plasma diagnosis apparatus may be used to analyze characteristics of the plasma 160, such as a density, an electron temperature, an ion density, an ion flux, or the like.

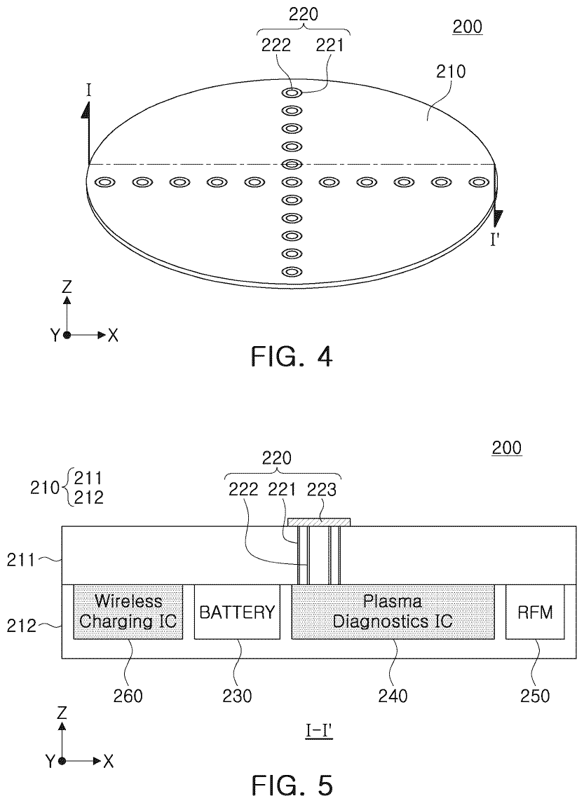

FIG. 4 is a view illustrating a plasma diagnosis apparatus 200 according to various example embodiments.

As illustrated in FIG. 4, a plasma diagnosis apparatus 200 may be implemented in a wafer form capable of performing auto-loading from a FOUP. The plasma diagnosis apparatus 200 may include at least one probe 220 disposed on a substrate 210. In this case, the substrate 210 may be a silicon (Si) substrate, but it should be understood that a material of the substrate 210 is not limited to silicon.

In various example embodiments, the substrate 210 may include an upper substrate and a lower substrate. The lower substrate may be stacked with the upper substrate in a Z-axis direction of FIG. 4. The substrate 210 illustrated in FIG. 4 may correspond to an upper surface of the upper substrate.

The probe 220 may be implemented as a single probe or a double probe. As an embodiment, FIG. 4 shows a double probe type. The probe 220 may include a first electrode 221 and a second electrode 222 disposed adjacent to the first electrode 221. For example, the first electrode 221 may be a positive electrode and the second electrode 222 may be a negative electrode.

In various example embodiments, a portion of the probe 220 may be disposed in a first direction (X-axis direction in FIG. 4) parallel to an upper surface of the substrate 210, and a different portion of the probe 220 may be disposed in a second direction (Y-axis direction in FIG. 4), parallel to the upper surface of the substrate 210 and orthogonal to the first direction. Arrangement of the probes 220 are not limited to an embodiment and may be arranged in various forms.

In various example embodiments, the plasma diagnosis apparatus 200 may be fixed on an electrostatic chuck inside an apparatus for fabricating a semiconductor device and may collect data for diagnosing characteristics of plasma in a state in which the plasma is generated inside the apparatus for fabricating a semiconductor device. In this case, the data may be collected using a current signal introduced from the probe 220. The characteristics of the plasma generated inside the apparatus for fabricating a semiconductor device may be diagnosed using the collected data, and the uniformity, density, distribution, or other characteristics of the plasma may be improved which can further improve the yield of a semiconductor device fabricated using the said semiconductor process.

FIG. 5 is a view illustrating a cross-section of the plasma diagnosis apparatus illustrated in FIG. 4, taken along direction I-I′, according to an embodiment.

Referring to FIG. 5, a plasma diagnosis apparatus 200 may include a substrate 210, a probe 220, a battery 230, a plasma diagnosis circuit (IC) 240, a wireless communication circuit (RFM) 250, and a wireless charging circuit (IC) 260.

In various example embodiments, the plasma diagnosis circuit 240 may include a transformer, a first circuit connected to a primary wound line of the transformer, a second circuit connected between a secondary wound line of the transformer and the probe, a current detection circuit connected to the primary wound line of the transformer, and a signal processing circuit generating data for diagnosing characteristics of the plasma using an output of the current detection circuit.

In various example embodiments, the substrate 210 may include an upper substrate 211 and a lower substrate 212. The lower substrate 212 may be stacked with the upper substrate 211 along a Z-axis of FIG. 5. At least one probe 220 may be disposed on the upper substrate 211. The battery 230, the plasma diagnosis circuit 240, the wireless communication circuit 250, and the wireless charging circuit 260 may be mounted on the lower substrate 212. The upper substrate 211 and the lower substrate 212 may be implemented in a wafer form.

The probe 220 may be disposed on the substrate 210 or inside the substrate 210. According to various example embodiments illustrated in FIG. 5, the probe 220 may be disposed on the upper substrate 211 which may be exposed to a plasma. The probe 220 may include a first electrode 221, a second electrode 222, and a protective layer 223. The second electrode 222 may be disposed adjacent to the first electrode 221. For example, the first electrode 221 may be a positive electrode, and the second electrode 222 may be a negative electrode. However, example embodiments are not limited thereto. The protective layer 223 may serve to protect the first electrode 221 and the second electrode 222 from the plasma and may be formed of a silicon (Si)-based material. For example, by using the wireless probe 220, characteristics such as an electron temperature, an ion density, an ion flux, or the like of the plasma may be diagnosed in-situ. Therefore, it is possible to have effects of reducing manpower operation and management costs of facilities.

As in an embodiment illustrated in FIG. 5, the battery 230 may be mounted on the lower substrate 212 and may supply power to the plasma diagnosis circuit 240 and the wireless communication circuit 250. The battery 230 may be a low-capacity battery, and for example, may be implemented as a low-capacity battery of about 20 mAh. The battery 230 may be repeatedly charged through the wireless charging circuit 260, and the plasma diagnosis apparatus 200 may be repeatedly used through the battery 230. For example, the low-capacity battery may be configured to satisfy conditions such as weight, thickness, or the like so that the plasma diagnosis apparatus may be transported by a FOUP. For example, the wireless charging circuit 260 may wirelessly charge the battery 230 and may include a receiver for wirelessly receiving power, and a transmitter for wirelessly transmitting power.

In various example embodiments, the plasma diagnosis circuit 240 may be mounted on the lower substrate 212 and may diagnose the plasma of a chamber through the probe 220. The plasma diagnosis circuit 240 may include a transformer connected to the probe 220, a current sensing resistor connected to a primary wound line of the transformer, an operational amplifier connected to the current sensing resistor, a pre-amplifier connected to an output terminal of the operational amplifier, and a signal processing circuit connected to the operational amplifier.

The plasma diagnosis circuit 240 may apply a voltage signal to the plasma through the probe 220, and a current signal may be generated in response to the voltage signal. Therefore, the current signal may be introduced from the plasma to the plasma diagnosis circuit 240 through the probe 220. The current signal introduced from the plasma through the probe 220 may be inputted to the operational amplifier through the transformer and the current sensing resistor. The operational amplifier and the pre-amplifier may convert the current signal into an output voltage signal. The signal processing circuit may convert the output voltage signal into frequency domain data. Characteristics of the plasma may be diagnosed by analyzing the frequency domain data.

The current signal generated from the plasma and introduced through the probe 220 may include noise generated by sources other than the plasma, and the noise may degrade measurement stability and accuracy of a diagnosis result of the plasma. In various example embodiments, the effect of the noise may be reduced by including a transformer in the plasma diagnosis circuit 240, and for example, a signal-to-noise ratio (SNR) may be increased. Additionally, the transformer may electrically separate the current detection circuit and a ground of the probe, to attenuate noise such as transient current or the like. Therefore, even when the noise is introduced into the probe 220, the plasma diagnosis apparatus 200 may be configured to accurately diagnose the plasma by filtering out the effect of the noise signal.

The wireless communication circuit 250 may be mounted on the lower substrate 212 and may wirelessly transmit a diagnosis result of the plasma diagnosis circuit 240 to an external device. The wireless communication circuitry 250 may use various forms of wireless communication such as, but not limited to, RF communication. The wireless communication circuit 250 may receive a request for the diagnosis result of the plasma diagnosis circuit 240 from the external device or may transmit the diagnosis result of the plasma diagnosis circuit 240 to the external device. In various example embodiments, the external device may be the server 3 of an embodiment illustrated in FIG. 1.

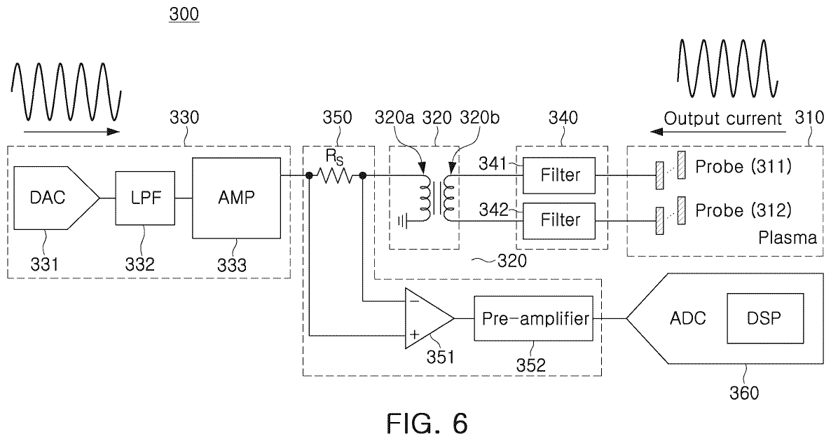

FIGS. 6 to 9 are circuit diagrams illustrating a plasma diagnosis circuit according to various example embodiments.

A plasma diagnosis circuit (300, 400, 500, and 600) according to various example embodiments may include a probe (310, 410, 510, and 610). A voltage signal having a predetermined (or, alternatively a desired) cycle may be applied to the probe (310, 410, 510, and 610), and a current signal may be introduced from plasma through the probe (310, 410, 510, and 610).

The probe (310, 410, 510, and 610) may be disposed on a substrate or inside the substrate. According to example embodiments illustrated in FIGS. 6 to 9, the probe (310, 410, 510, and 610) may be disposed on the substrate to be exposed to the plasma. The probe (310, 410, 510, and 610) may include a first electrode (311, 411, 511, and 611) and a second electrode (312, 412, 512, and 612) disposed adjacent to the first electrode. In various example embodiments, the first electrode (311, 411, 511, and 611) may be a positive electrode, and the second electrode (312, 412, 512, and 612) may be a negative electrode.

Referring to FIGS. 6 to 9, the plasma diagnosis circuit (300, 400, 500, and 600) may include a transformer (320, 420, 520, and 620), a first circuit (330, 430, 530, and 630), a second circuit (340, 440, 540, and 640), a current detection circuit (350, 450, 550, and 650), and a signal processing circuit (360, 460, 560, and 660).

Referring to FIGS. 6 to 9, the first circuit (330, 430, 530, and 630) may be connected to a primary wound line (320a, 420a, 520a, and 620a) of the transformer (320, 420, 520, and 620). The first circuit (330, 430, 530, and 630) may include a signal supply circuit that outputs a voltage signal having a predetermined (or, alternatively a desired) cycle to the primary wound line (320a, 420a, 520a, and 620a) of the transformer (320, 420, 520, and 620). In example embodiments illustrated in FIGS. 6 to 9, the signal supply circuit may include a digital-to-analog converter (DAC; 331, 431, 531, and 631) generating the voltage signal having the predetermined (or, alternatively a desired) cycle, and, in addition to the digital-to-analog converter (331, 431, 531, and 631), an oscillator, a voltage generator, a function generator, or the like may be applied. The signal supply circuit may include a low-pass filter (LPF; 332, 432, 532, 632) filtering an output signal of the digital-to-analog converter (331, 431, 531, and 631), and an amplifier (AMP; 333, 433, 533, and 633) amplifying the output signal of the low-pass filter (332, 432, 532, and 632).

Referring to FIGS. 6 to 9, the second circuit (340, 440, 540, and 640) may transmit the voltage signal having the predetermined (or, alternatively a desired) cycle output by the first circuit (330, 430, 530, and 630) to the probe (310, 410, 510, and 610). The current signal may be generated in the plasma formed on a plasma diagnosis apparatus including the plasma diagnosis circuit (300, 400, 500, and 600) by the voltage signal transmitted to the probe (310, 410, 510, and 610). The current signal generated from the plasma may be introduced through the probe (310, 410, 510, and 610).

The second circuit (340, 440, 540, and 640) may receive the current signal introduced through the probe (310, 410, 510, and 610). According to example embodiments illustrated in FIGS. 6 to 9, the second circuit (340, 440, 540, and 640) may include a filter (341, 342, 441, 442, 541, 542, 641, and 642), and the filter (341, 342, 441, 442, 541, 542, 641, and 642) may be configured to filter RF noise introduced through the probe (310, 410, 510, and 610).

Specifically, the filter (341, 342, 441, 442, 541, 542, 641, and 642) may block a direct current (DC) component included in a current signal introduced through the probe (310, 410, 510, and 610), and may selectively pass a current signal of a specific frequency band. The filter (341, 342, 441, 442, 541, 542, 641, and 642) may be implemented using a passive element or an active element. The filter (341, 342, 441, 442, 541, 542, 641, and 642) may be connected between the probe (310, 410, 510, and 610) and a secondary wound line (320b, 420b, 520b, and 620b) of the transformer (320, 420, 520, and 620).

According to embodiments illustrated in FIGS. 6 to 9, the filter (341, 342, 441, 442, 541, 542, 641, and 642) may include a first filter (341, 441, 541, and 641) connected to the first electrode (311, 411, 511, and 611), and a second filter (342, 442, 542, and 642) connected to the second electrode (312, 412, 512, and 612). The first filter (341, 441, 541, and 641) may block a DC component included in a current signal introduced through the first electrode (311, 411, 511, and 611), or may pass only a current signal of a specific frequency band. The second filter (342, 442, 542, and 642) may block a DC component included in a current signal introduced through the second electrode (312, 412, 512, and 612), or may pass only a current signal of a specific frequency band.

Referring to FIGS. 6 to 9, the current detection circuit (350, 450, 550, and 650) may be connected to the primary wound line (320a, 420a, 520a, and 620a) of the transformer (320, 420, 520, and 620). The current detection circuit (350, 450, 550, and 650) may include a current sensing resistor (Rs; Rs1 and Rs2) connected to the primary wound lines (320a, 420a, 520a, and 620a) of the transformer (320, 420, 520 and 620), and an operational amplifier (351, 451, 551, and 651) connected to the current sensing resistor Rs. An input terminal of the operational amplifier (351, 451, 551, and 651) may be connected to both ends of the current sensing resistor Rs, and the operational amplifier (351, 451, 551, and 651) may be configured to output an output voltage signal corresponding to a potential difference generated from the current sensing resistor Rs by a current signal.

The signal processing circuit (360, 460, 560, and 660) may generate frequency domain data for diagnosing the plasma using an output of the current detection circuit (350, 450, 550, and 650). For example, the signal processing circuit (360, 460, 560, and 660) may generate the frequency domain data by sampling and converting the output of the current detection circuit (350, 450, 550, and 650) into a frequency domain. Referring to FIGS. 6 to 9, the signal processing circuit (360, 460, 560, and 660) may include an analog-to-digital converter (ADC) converting the output voltage signal of the operational amplifier (351, 451, 551, and 651) into a digital signal, and according to various example embodiments, may also include a microcontroller unit (MCU), a complex programmable logic device (CPLD), a field programmable gate array (FPGA), or an application-specific integrated circuit (ASIC).

As an example, the signal processing circuit (360, 460, 560, and 660) may include a digital signal processor (DSP). The digital signal processor may selectively process a signal, such as passing only a signal of a specific frequency band, among outputs of the analog-to-digital converter, using a function library, converting a magnitude of an envelope of a signal, or the like.

According to some example embodiment as illustrated in FIGS. 6 to 9, the current detection circuit (350, 450, 550, and 650) may include a pre-amplifier (352, 452, 552 and 652) connected between the output terminal of the operational amplifier (351, 451, 551, and 651) and the signal processing circuit (360, 460, 560 and 660). The pre-amplifier (352, 452, 552, and 652) may adjust a common mode level and a signal magnitude of a signal applied to the signal processing circuit (360, 460, 560, and 660). The pre-amplifier (352, 452, 552, and 652) may perform a function of adjusting a bandwidth of the signal processing circuit (360, 460, 560, and 660). In addition, the pre-amplifier (352, 452, 552, and 652) may be configured to perform a function of anti-aliasing filtering that prevents the aliasing of a signal having a bandwidth equal to or greater than a certain frequency.

In some example embodiments as illustrated in FIG. 6, a current detection circuit 350 may include a current sensing resistor Rs. One end of the current sensing resistor Rs may be connected to a first circuit 330 and a non-inverting input node of an operational amplifier 351, and the other end of the current sensing resistor Rs may be connected to one end of a primary wound line 320a of a transformer 320 and an inverting input node of the operational amplifier 351.

The one end of the primary wound line 320a of the transformer 320 may be connected to the current sensing resistor Rs, and the other end of the primary wound line 320a of the transformer 320 may be connected to a ground. One end of a secondary wound line 320b of the transformer 320 may be connected to a first filter 341, and the other end of the secondary wound line 320b of the transformer 320 may be connected to a second filter 342. For example, the transformer 320 may be a balun transformer, and a ground of the current detection circuit 350 connected to the primary wound line 320a and a ground of a probe 310 connected to the secondary wound line 320b may be separated from each other by the transformer 320. Therefore, unnecessary noise introduced into the probe 310 may be attenuated, and thus, accuracy of plasma diagnosis or measurement stability may be improved.

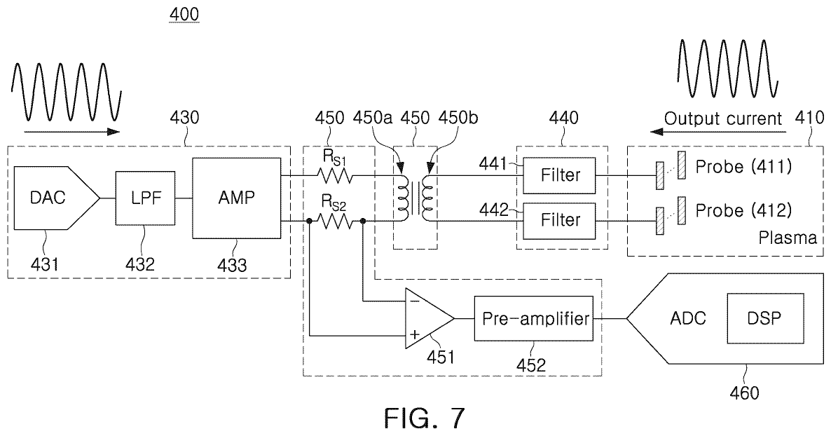

In embodiments illustrated in FIGS. 7 to 9, a current sensing resistor Rs may include a first sensing resistor Rs1 and a second current sensing resistor Rs2. One end of the first current sensing resistor Rs1 may be connected to a first circuit (430, 530 and 630), and the other end of the first current sensing resistor Rs1 may be connected to one end of a primary wound line (420a, 520a, and 620a) of a transformer (420, 520, and 620). One end of the second current sensing resistor Rs2 may be connected to the first circuit (430, 530, and 630) and a non-inverting input node of an operational amplifier (451, 551, and 651), and the other end of the second current sensing resistor Rs2 may be connected to the other end of the primary wound line (420a, 520a, and 620a) of the transformer (420, 520, and 620) and an inverting input node of the operational amplifier (451, 551, and 651).

In embodiments illustrated in FIGS. 7 to 9, the one end of the primary wound line (420a, 520a, and 620a) of the transformer (420, 520, and 620) may be connected to the first current sensing resistor Rs1, and the other end of the primary wound line (420a, 520a, and 620a) of the transformer (420, 520, and 620) may be connected to the second current sensing resistor Rs2. One end of a secondary wound line (420b, 520b, and 620b) of the transformer (420, 520, and 620) may be connected to a first filter (441, 541, and 641), and the other end of the secondary wound line (420b, 520b, and 620b) of the transformer (420, 520, and 620) may be connected to a second filter (442, 542, and 642). For example, the transformer (420, 520, and 620) may be an isolation transformer. Wound lines included inside the transformer (420, 520, and 620) may induce an electromagnetic induction phenomenon, and Lenz's law may be applied thereto. For this reason, even when a transient current is introduced through a probe (410, 510, and 610), the transient current may be attenuated by the transformer (420, 520, and 620) not to pass over to the primary wound line (420a, 520a, and 620a). Therefore, plasma diagnosis accuracy or measurement stability of the plasma diagnosis apparatus may be improved.

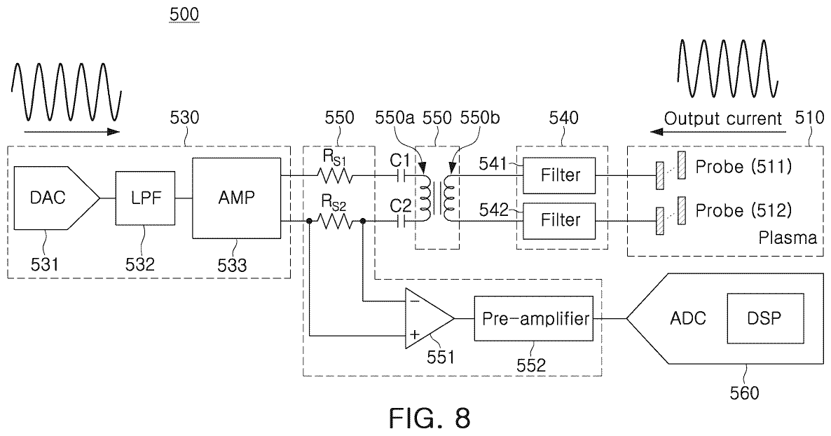

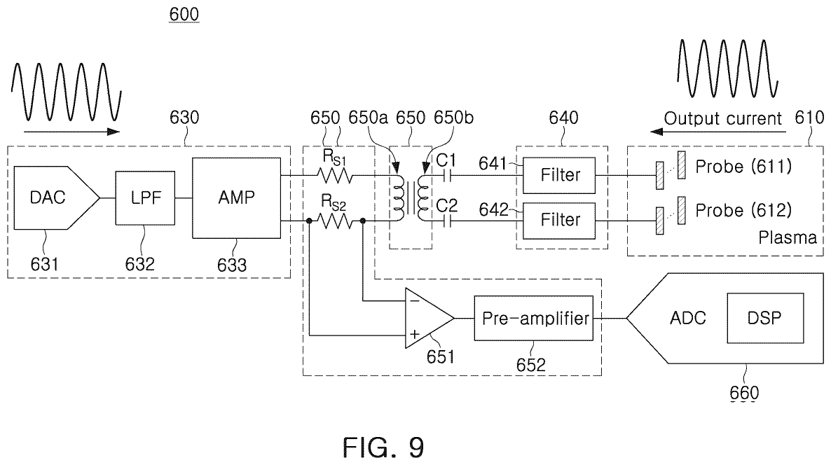

In various example embodiments as illustrated in FIGS. 8 and 9, capacitors C1 and C2 may be connected to a plasma diagnosis circuit (500 and 600). According to an example embodiment as illustrated in FIG. 8, a first capacitor C1 may be connected between one end of a primary wound line 520a of a transformer 520 and a first current sensing resistor Rs1, and a second capacitor C2 may be connected between the other end of the primary wound line 520a of the transformer 520 and a second current sensing resistor Rs2. According to an embodiment illustrated in FIG. 9, a first capacitor C1 may be connected between one end of a secondary wound line 620b of a transformer 620 and a first filter 641, and a second capacitor C2 may be connected between the other end of the secondary wound line 620b of the transformer 620 and a second filter 642. As the capacitors C1 and C2 are connected to the plasma diagnosis circuit (500 and 600), a DC component included in a current signal introduced through a probe (510 and 610) may be effectively blocked. Therefore, diagnosis may be made of a floating potential of the plasma.

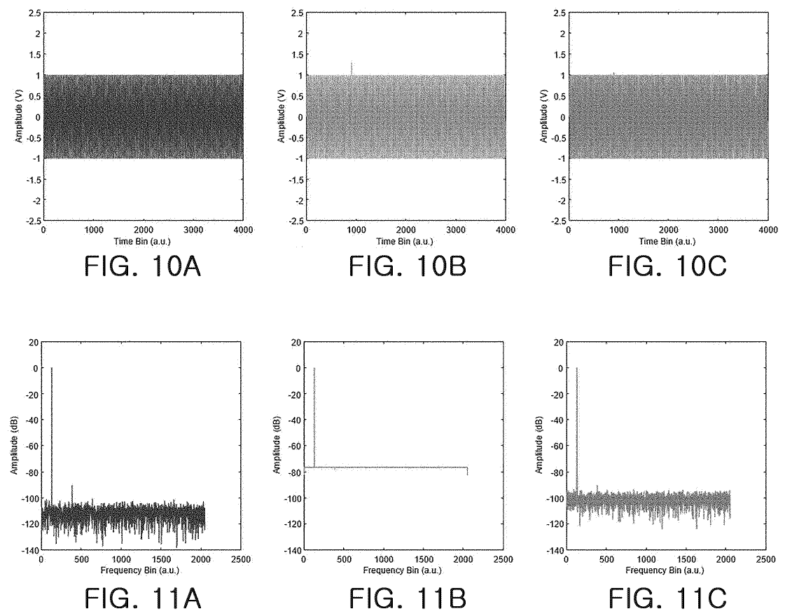

FIGS. 10A to 10C illustrate outputs of a current detection circuit according to some example embodiments.

A plasma diagnosis circuit may apply a voltage signal to plasma through a probe, and a current signal generated in the plasma may be introduced into the plasma diagnosis circuit through the probe. The plasma diagnosis circuit may include a transformer, a filter, a signal supply circuit, a current detection circuit, and a signal processing circuit, and the current detection circuit may include a current sensing resistor, an operational amplifier, and a pre-amplifier. The filter may be connected to the probe, and a secondary wound line of the transformer may be connected to the filter. A primary wound line of the transformer may be connected to the current sensing resistor, and the operational amplifier may be connected to the current sensing resistor. The pre-amplifier may be connected to an output terminal of the operational amplifier, and the signal processing circuit may be connected to an output terminal of the pre-amplifier.

A current signal introduced from the plasma through the probe may be converted into an output voltage signal through the filter, the transformer, the current sensing resistor, the operational amplifier, and the pre-amplifier. For example, an output of the current detection circuit may be an output voltage signal that may be an output of the pre-amplifier. In various example embodiments, the output voltage signal may be a signal in a time domain.

FIG. 10A is a graph illustrating an output voltage signal generated from a plasma diagnosis circuit when a transformer is not applied to the plasma diagnosis circuit included in a plasma diagnosis apparatus and noise is not included in a current signal introduced through a probe. In an example embodiment as illustrated in FIG. 10A, while the plasma diagnosis circuit detects the current signal, a magnitude of the output voltage signal may fall within a certain range.

FIG. 10B is a graph illustrating an output voltage signal generated from a plasma diagnosis circuit when a transformer is not applied to the plasma diagnosis circuit included in a plasma diagnosis apparatus and noise is included in a current signal introduced through a probe. In an embodiment illustrated in FIG. 10B, while the plasma diagnosis circuit detects the current signal, a magnitude of the output voltage signal may fall within a certain range, but a noise voltage momentarily exceeding the certain range may be detected due to the noise included in the current signal. The noise voltage may be generated by common mode noise or a transient current included in the current signal introduced through the probe.

FIG. 10C is a graph illustrating an output voltage signal generated from a plasma diagnosis circuit when a transformer is applied to the plasma diagnosis circuit included in a plasma diagnosis apparatus and noise is included in a current signal introduced through a probe. In an embodiment illustrated in FIG. 10C, while the plasma diagnosis circuit detects the current signal, a magnitude of the output voltage signal may fall within a certain range, but a noise voltage momentarily exceeding the certain range may be detected due to the noise included in the current signal.

However, a magnitude of the noise voltage illustrated in an example embodiment as illustrated in FIG. 10B may be greater than a magnitude of the noise voltage illustrated in another example embodiment as illustrated in FIG. 10C. This may be a difference depending on whether the plasma diagnosis circuit includes the transformer.

For example, when a plasma diagnostic circuit includes a transformer, a circuit for detecting a current signal may be connected to a primary wound line of the transformer, and a probe may be connected to a secondary wound line of the transformer. Therefore, noise included in the current signal introduced through the probe may not be transmitted to the circuit for detecting the current signal due to insulation characteristics of the transformer, and the noise included in the current signal may be attenuated. For example, the effect by the noise included in the current signal introduced through the probe on the circuit for detecting the current signal may be reduced by the transformer.

FIGS. 11A to 11C illustrate results of converting the output of the current detection circuit of FIGS. 10A to 10C into frequency domains.

FIGS. 11A to 11C are views in which Fourier transform (FT) is applied to an output of the current detection circuit of FIGS. 10A to 10C, and the output of the current detection circuit of FIGS. 10A to 10C may be an output voltage signal that may be an output of a pre-amplifier. FIGS. 11A to 11C illustrate frequency domain data, and the frequency domain data may be an output voltage signal based on frequency (Hz). An example embodiment as illustrated in FIGS. 11A to 11C, the output voltage signal based on frequency may be expressed in decibel (dB) units. For the Fourier transform (FT), a discrete Fourier transform (DFT) or a fast Fourier transform (FFT) may be used.

For example, a signal processing circuit may include an analog-to-digital converter (ADC) and a peripheral circuit. The analog-to-digital converter (ADC) may be configured to convert an output voltage signal of an operational amplifier into a digital signal, and may include an MCU, a CPLD, a FPGA, or an ASIC according to embodiments. The peripheral circuit may perform Fourier transform (FT) on the converted digital signal.

The signal processing circuit may also include a digital signal processor (DSP). The digital signal processor (DSP) may selectively process a signal by passing only a signal of a specific frequency band among outputs of an analog-to-digital converter (ADC), using a function library, or by converting a magnitude of an envelope of a signal.

FIG. 11A is a view in which Fourier transform (FT) is applied to the output voltage signal of FIG. 10A. As described above with reference to FIG. 10A, FIG. 11A is a graph illustrating frequency domain data generated from a plasma diagnosis circuit when a transformer is not applied to the plasma diagnosis circuit and noise is not included in a current signal introduced through a probe. Referring to the frequency domain data illustrated in FIG. 11A, peak values of a basic frequency band and a harmonic frequency band may appear higher than a noise floor value. Therefore, a diagnosis of the plasma using the peak values is possible.

As illustrated in FIG. 11A, a plasma diagnosis apparatus may transmit frequency domain data converted to a frequency domain to a server of a system or the like. The server may determine the peak values in the basic frequency band and the harmonic frequency band using the frequency domain data and may determine characteristics of plasma such as an electron temperature, a density of the plasma, or the like, based thereon. For example, a current signal generated in the plasma may be analyzed using the frequency domain data, and the plasma may be diagnosed using an analysis result of the current signal. The server may adjust control variables for an apparatus for fabricating a semiconductor device into which the plasma diagnosis apparatus is inserted using results of determining the characteristics of the plasma, and accordingly, the characteristics of the plasma generated inside the apparatus for fabricating a semiconductor device may be changed.

FIG. 11B is a view in which Fourier transform (FT) is applied to the output voltage signal of FIG. 10B. As described above with reference to FIG. 10B, FIG. 11B is a graph illustrating frequency domain data generated from a plasma diagnosis circuit when a transformer is not applied to the plasma diagnosis circuit and noise is included in a current signal introduced through a probe. Referring to the frequency domain data illustrated in FIG. 11B, peak values of a harmonic frequency band may not be distinguished from a noise floor value. Therefore, plasma diagnosis using the peak values is impossible.

For example, when the noise included in the introduced current signal is not blocked, the peak values of the harmonic frequency band may not be detected from the frequency domain data. Therefore, the server may diagnose characteristics of the plasma based only on the peak values in the basic frequency band, and accuracy of the diagnosis result may be low.

FIG. 11C is a view in which Fourier transform (FT) is applied to the output voltage signal of FIG. 10C. As described above with reference to FIG. 10C, FIG. 11C is a graph illustrating frequency domain data generated from a plasma diagnosis circuit when a transformer is applied to the plasma diagnosis circuit and noise is included in a current signal introduced through a probe. Referring to the frequency domain data as illustrated in FIG. 11C, peak values of a harmonic frequency band may be distinguished from a noise floor value. Therefore, plasma diagnosis using the peak values is possible.

In FIG. 11C, noise may be included in the current signal introduced through the probe, but the transformer included in the plasma diagnosis circuit may attenuate an effect of the noise. Due to insulation characteristics of the transformer, noise such as a transient current or the like introduced through the probe may be attenuated. Therefore, the transformer may reduce the influence of a transient current signal and the noise included in the current signal on analyzing the frequency domain data. Therefore, it is possible to accurately diagnose characteristics of the plasma and precisely control an apparatus for fabricating a semiconductor device using the diagnostic results, thereby improving process distribution or yield of the apparatus for fabricating a semiconductor device.

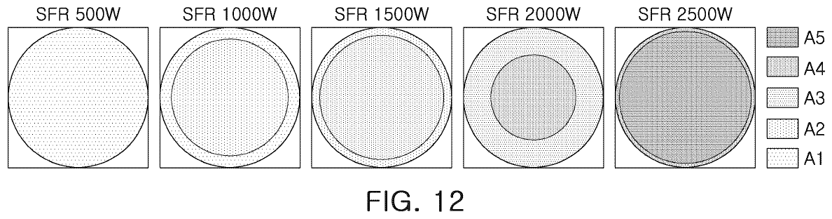

FIG. 12 illustrates plasma density diagnosis results according to an example embodiment.

In some example embodiments, FIG. 12 may be argon (Ar) plasma density diagnosis results according to radio frequency (RF) power of an inductively coupled plasma (ICP) facility to which a plasma diagnosis apparatus is applied. In order of increasing plasma density, the regions are shown as first region (A1), second region (A2), third region (A3), fourth region (A4), and fifth region (A5). Referring to FIG. 12, when plasma is formed with a plasma diagnosis apparatus of the present inventive concepts inserted into the ICP facility, plasma density values may be diagnosed. In this example case, a plasma density may be diagnosed in-situ.

In some example embodiments, a circle as illustrated in FIG. 12 may be a representation of the plasma diagnosis apparatus as implemented in a wafer form. A small circle illustrated inside the plasma diagnosis apparatus may be a probe exposed to the plasma, and the plasma diagnosis apparatus may include at least one probe. A portion of the probe may be disposed in a first direction, parallel to an upper surface of a substrate of the plasma diagnosis apparatus, and a different portion of the probe may be disposed in a second direction, parallel to the upper surface of the substrate and perpendicular to the first direction.

The plasma diagnosis apparatus may apply a voltage signal having a predetermined (or, alternatively a desired) cycle to the probe, and a current signal may be generated in the plasma in response to the voltage signal applied to the probe. The plasma diagnosis apparatus may detect the current signal generated in the plasma through the probe and may transmit data to a server. The server may diagnose characteristics of the plasma using said data, and the characteristics of the plasma may include a density and uniformity of the plasma.

In an example embodiment as illustrated in FIG. 12, the density of plasma generated inside an apparatus for fabricating a semiconductor device may increase linearly as RF power increases. In addition, even with the same RF power source, it is possible to observe a distribution of the plasma density in which the density of the plasma increases closer to a center of the plasma diagnosis apparatus.

When results of diagnosing the density of the plasma by inserting the plasma diagnosis apparatus of the present inventive concept into the apparatus for fabricating a semiconductor device are different from the desired density profile of the plasma, as illustrated in an example embodiment in FIG. 12 showing one such desired example profile, the density of the plasma may be corrected by controlling the apparatus for fabricating a semiconductor device. For example, an amount of source gas or reaction gas, an injection rate of the source gas or the reaction gas, a temperature inside the apparatus for fabricating a semiconductor device, or the like may be adjusted to correct the profile of the plasma density as desired.

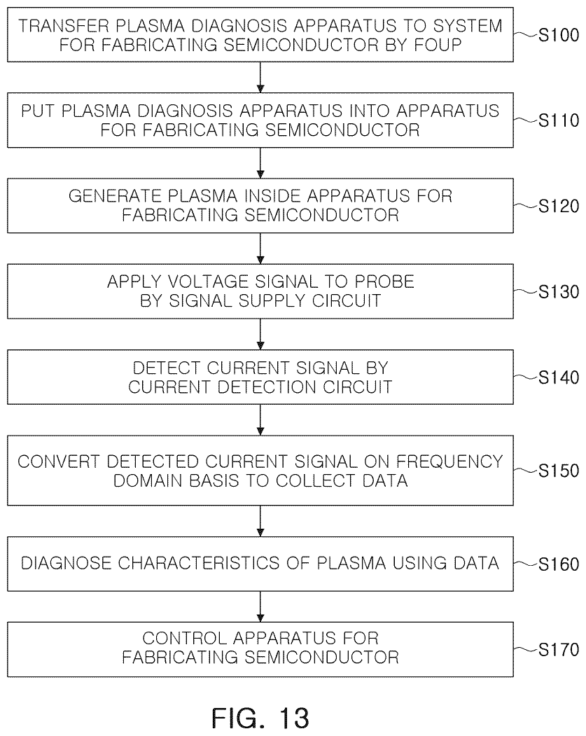

FIG. 13 is a flowchart illustrating a plasma diagnosis process according to an example embodiment.

A plasma diagnosis apparatus may be transferred to a system for fabricating a semiconductor device by a FOUP (S100). In this case, the plasma diagnosis apparatus may satisfy conditions such as a weight, a thickness, a size, or the like that may be transported by the FOUP. The transferred plasma diagnosis apparatus may be put into an apparatus for fabricating a semiconductor device (S110), and, in this case, may pass through a wafer transport device and a load lock chamber of a system for fabricating a semiconductor device. The plasma diagnosis apparatus may be fixed on an electrostatic chuck inside the apparatus for fabricating a semiconductor device. In this case, the plasma diagnosis apparatus may be implemented in a wafer form and may diagnose the plasma in-situ by including a low-capacity battery and a low-power plasma diagnosis circuit.

Thereafter, the plasma may be generated inside the apparatus for fabricating a semiconductor device (S120), and specifically, the plasma may be generated inside a chamber included in the apparatus for fabricating a semiconductor device. While a gas supplier supplies at least one of source gas or reaction gas to an internal space of the chamber, a power supplier may supply electric power to an electrode installed in the internal space of the chamber. The source gas or the reactive gas may collide while being accelerated by electric energy in the internal space of the chamber by the supplied electric power, and then a chain reaction may occur to generate plasma.

Thereafter, a signal supply circuit of the plasma diagnosis apparatus may apply a voltage signal to a probe (S130), and the voltage signal may have a predetermined (or, alternatively a desired) cycle. The applied voltage signal may generate a current signal introduced into the plasma diagnosis circuit. A current detection circuit may detect the current signal (S140), and the detection result may be an output voltage signal. The output voltage signal may be converted into data on a frequency domain basis through a signal processing circuit, and the data may be collected from a server included in the system (S150). When converting the output voltage signal on a frequency domain basis, a discrete Fourier transform (DFT) or a fast Fourier transform (FFT) may be used.

The server may diagnose characteristics of the plasma using the received data (S160). The characteristics of the plasma may be diagnosed using a voltage signal of strong intensity appearing in a basic frequency band and a harmonic frequency band, and the characteristics of the plasma may include an electron temperature, an ion density, an ion flux, or the like of the plasma.

The apparatus for fabricating a semiconductor device may be controlled using the result of diagnosing the characteristics of the plasma (S170). A temperature inside the apparatus for fabricating a semiconductor device, an amount of supplied source gas or reactive gas, a rate at which the source gas or the reactive gas is supplied, a gap between an electrode and an electrostatic chuck, or the like may be adjusted to correct the characteristics of the plasma as desired.

For example, the plasma may be diagnosed by putting the plasma diagnosis apparatus into the apparatus for fabricating a semiconductor device before a start or after an end of a semiconductor process. For example, for the purpose of diagnosing performance of the apparatus for fabricating a semiconductor device after repairing the apparatus for fabricating a semiconductor device, plasma may be diagnosed and the apparatus for fabricating a semiconductor device may be calibrated to improve the dispersion of the plasma and/or yield of the semiconductor device.

In addition, the plasma diagnosis apparatus according to an embodiment may diagnose characteristics of the plasma in-situ without a preventive maintenance (PM) operation such as opening of the chamber, thereby reducing manpower operations and management costs of the facility.

According to various example embodiments, a plasma diagnosis apparatus capable of collecting data for determining characteristics of plasma may be put into an apparatus for fabricating a semiconductor device before a start or after an end of a semiconductor process to diagnose the plasma. The plasma diagnosis apparatus may include a transformer, and a ground of a primary side to which a signal detection circuit is connected and a secondary side to which a probe is connected may be separated and insulated from each other by the transformer to attenuate noise components generated in the plasma and introduced through the probe, to improve performance of the plasma diagnosis apparatus.

Various advantages and effects of the present inventive concept are not limited to the above description and will be more easily understood in the process of describing specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A plasma diagnosis apparatus comprising:
an upper substrate;
a lower substrate stacked with the upper substrate;
at least one probe on the upper substrate;
a plasma diagnosis circuit mounted in the lower substrate and configured to diagnose plasma in a chamber through the probe;
a wireless communication circuit mounted in the lower substrate and configured to wirelessly transmit a result of the plasma diagnosis circuit to an external device;
a battery mounted in the lower substrate and configured to supply power to the plasma diagnosis circuit and the wireless communication circuit; and
a wireless charging circuit mounted in the lower substrate and configured to wirelessly charge the battery,
wherein the plasma diagnosis circuit includes a transformer, a first circuit connected to a primary wound line of the transformer, a second circuit connected between a secondary wound line of the transformer and the probe, a current detection circuit connected to the primary wound line of the transformer, and a signal processing circuit configured to generate data with diagnostic characteristics of the plasma based on an output of the current detection circuit.

2. The plasma diagnosis apparatus of claim 1, wherein the upper substrate and the lower substrate are implemented in a wafer form.

3. The plasma diagnosis apparatus of claim 1, wherein the probe comprises a first electrode and a second electrode adjacent to the first electrode.

4. The plasma diagnosis apparatus of claim 1, wherein a portion of the probe is in a first direction, parallel to an upper surface of the upper substrate, and a different portion of the probe is in a second direction, parallel to the upper surface of the upper substrate and orthogonal to the first direction.

5. The plasma diagnosis apparatus of claim 1, wherein the first circuit comprises a signal supply circuit configured to output a voltage signal having a cycle to the primary wound line of the transformer,
the second circuit comprises a filter connected between the probe and the secondary wound line of the transformer,
the current detection circuit comprises a current sensing resistor connected to the primary wound line of the transformer, and an operational amplifier connected to the current sensing resistor, and
the signal processing circuit comprises an analog-to-digital converter configured to convert an output voltage signal of the operational amplifier into a digital signal.

6. The plasma diagnosis apparatus of claim 5, wherein the signal supply circuit comprises:
a digital-to-analog converter configured to generate a voltage signal having a cycle;
a low pass filter configured to filter an output signal of the digital-to-analog converter; and
an amplifier configured to amplify an output signal of the low pass filter.

7. The plasma diagnosis apparatus of claim 5, wherein the filter is configured to filter RF noise introduced through the probe.

8. The plasma diagnosis apparatus of claim 5, wherein the current detection circuit comprises a pre-amplifier connected between an output terminal of the operational amplifier and the signal processing circuit, and configured to adjust a common mode level and a signal magnitude of a signal applied to the signal processing circuit.

9. The plasma diagnosis apparatus of claim 7, wherein the probe comprises a first electrode and a second electrode adjacent to the first electrode, and
wherein the filter comprises a first filter connected to the first electrode and a second filter connected to the second electrode.

10. The plasma diagnosis apparatus of claim 9, wherein one end of the primary wound line of the transformer is connected to the current sensing resistor, and an other end of the primary wound line of the transformer is connected to a ground, and
one end of the secondary wound line of the transformer is connected to the first filter, and an other end of the secondary wound line of the transformer is connected to the second filter.

11. The plasma diagnosis apparatus of claim 9, wherein the current sensing resistor comprises a first current sensing resistor and a second current sensing resistor,
wherein one end of the primary wound line of the transformer is connected to the first current sensing resistor, and an other end of the primary wound line of the transformer is connected to the second current sensing resistor,
wherein one end of the secondary wound line of the transformer is connected to the first filter, and an other end of the secondary wound line of the transformer is connected to the second filter.

12. The plasma diagnosis apparatus of claim 11, further comprising:
a first capacitor, connected between the one end of the primary wound line of the transformer and the first current sensing resistor, and
a second capacitor, connected between the other end of the primary wound line of the transformer and the second current sensing resistor.

13. The plasma diagnosis apparatus of claim 11, further comprising:
a first capacitor, connected between the one end of the secondary wound line of the transformer and the first filter, and
a second capacitor, connected between the other end of the secondary wound line of the transformer and the second filter.

14. A plasma diagnosis apparatus comprising:
at least one probe;
a transformer connected to the probe;
a current sensing resistor connected to a primary wound line of the transformer;
an operational amplifier connected to the current sensing resistor;
a pre-amplifier connected to an output terminal of the operational amplifier; and
a signal processing circuit connected to the operational amplifier,
wherein a current signal from plasma introduced through the probe is input to the operational amplifier through the transformer and the current sensing resistor,
the operational amplifier and the pre-amplifier are configured to convert the current signal into an output voltage signal, and
the signal processing circuit is configured to convert the output voltage signal into frequency domain data.

15. The plasma diagnosis apparatus of claim 14, wherein the probe comprises a first electrode and a second electrode adjacent to the first electrode,
wherein the first electrode is connected to one end of a secondary wound line of the transformer, and the second electrode is connected to an other end of the secondary wound line of the transformer.

16. The plasma diagnosis apparatus of claim 14, wherein the signal processing circuit comprises an analog-to-digital converter configured to convert the output voltage signal into a digital signal.

17. The plasma diagnosis apparatus of claim 15, further comprising:
a first filter and a first capacitor, connected between the first electrode and the one end of the secondary wound line of the transformer, and
a second filter and a second capacitor, connected between the second electrode and the other end of the secondary wound line of the transformer.

18. The plasma diagnosis apparatus of claim 17, wherein one end of the primary wound line of the transformer is connected to the current sensing resistor, and an other end of the primary wound line of the transformer is connected to a ground.

19. The plasma diagnosis apparatus of claim 17, wherein the current sensing resistor comprises a first current sensing resistor and a second current sensing resistor,
wherein one end of the primary wound line of the transformer is connected to the first current sensing resistor, and an other end of the primary wound line of the transformer is connected to the second current sensing resistor.

20. An apparatus for fabricating a semiconductor device, comprising:
a chamber;
an electrostatic chuck in a space inside the chamber;
a gas supplier configured to supply at least one of a source gas or a reaction gas;
a power supplier configured to supply bias power to an electrode in the space inside the chamber; and
a controller configured to control the power supplier, the gas supplier, and the electrostatic chuck,
wherein, a plasma diagnosis apparatus is on the electrostatic chuck, the controller is configured to control the power supplier to supply the bias power to the electrode such that plasma is generated in the space inside the chamber, and the controller is configured to control the gas supplier to supply at least one of the source gas or the reaction gas,
the controller is configured to control the gas supplier, the power supplier, and the electrostatic chuck using data acquired from the plasma by the plasma diagnosis apparatus, and
the plasma diagnosis apparatus includes a probe, a current detection circuit detecting a current signal introduced through the probe, and a transformer having a primary wound line connected to the current detection circuit and a secondary wound line connected to the probe.
